(19) United States
(12) Patent Application Publication
(10) Pub. No.: US 2008/0150054 A1
(43) Pub. Date: Jun. 26, 2008

(54) IMAGE SENSOR AND METHOD FOR MANUFACTURING THE SAME

(75) Inventor: Shang Won KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/944,811

(22) Filed: Nov. 26, 2007

(30) Foreign Application Priority Data
Dec. 26, 2006 (KR) 10-2006-0133524

(51) Int. Cl. H01L 31/0232; H01L 31/18

(52) U.S. Cl. 257/432; 438/70; 257/E31.127; 257/E21.598

(57) ABSTRACT

An image sensor and a method for manufacturing the same. In one example embodiment of the invention, an image sensor includes a semiconductor substrate in which a plurality of photodiodes are formed, an insulating layer formed on the semiconductor substrate, a color filter layer formed on the insulating layer, a planarization layer formed on a whole surface of the resultant comprising the color filter layer and having a plurality of concave parts disposed at regular intervals, and a plurality of micro lenses formed within each of the concave portions of the planarization layer and disposed at regular intervals.

### CROSS-REFERENCE TO RELATED APPLICATION

This application claims priority to Korean Application No. 10-2006-0133524, filed on Dec. 26, 2006, which is incorporated herein by reference in its entirety.

### BACKGROUND

1. Field of the Invention

The invention relates to an image sensor having substantially uniform micro lenses and a method for manufacturing the same.

2. Description of the Related Art

In general, an image sensor is a semiconductor device capable of converting an optical image into an electrical signal. Image sensors can generally be classified into Charge Coupled Device (CCD) image sensors and Complementary Metal Oxide Semiconductor (CMOS) image sensors.

An image sensor generally includes a photodiode unit capable of sensing light and a logic circuit unit capable of converting the light to an electrical data signal. As the amount of light received by the photodiode unit increases, the photosensitivity of the image sensor improves.

In order to improve the photosensitivity of an image sensor, a ratio between an occupation area of a photodiode and a total area of the image sensor can be increased, or a path of light incident on a region other than the photodiode can be altered to focus the light on the photodiode.

A typical device that can be employed to focus light on a photodiode is a micro lens. A micro lens is a convex lens formed of a material having a good light transmittance. A micro lens can be positioned over a photodiode to refract a path of incident light and direct a greater quantity of the light into a photodiode. If light is incident in parallel with an optical axis of the micro lens, the light is refracted by the micro lens and is focused at a predetermined position on the optical axis.

In general, an image sensor includes, among other things, a photodiode, an insulating layer, a color filter layer, and a micro lens. The photodiode senses and converts light into an electrical signal. The insulating layer provides insulation between metal wires. The color filter layer generally filters the light into its red, green, and blue (RGB) components. The micro lens focuses light on the photodiode.

As disclosed in FIG. 1, an insulating layer 20 is formed on a semiconductor substrate 10 in which a plurality of photodiodes 40 are formed. RGB color filter layers 30 are formed on the insulating layer 20 to correspond to the plurality of photodiodes 40.

A planarization layer 25 is formed to planarize a non-uniform surface of the color filter layers 30. Micro lenses 50 are formed on the planarization layer 25 to correspond to the plurality of photodiodes 40 and the color filter layers 30. The micro lenses 50 are configured as convex lenses to focus light on the plurality of photodiodes 40. The micro lenses 50 can be manufactured using the prior art photolithography process of FIGS. 2A-2C.

As disclosed in FIG. 2A, a photoresist 60, which is a micro lens substance, is coated on the planarization layer 25 and is covered with a mask 61. As disclosed in FIG. 2B, the photoresist 60 is then exposed using a defocus phenomenon and is patterned to have a trapezoidal shape.

As disclosed in FIG. 2C, the trapezoidal photoresist pattern is then heated to a melting point causing the trapezoidal photoresist pattern to reflow. During a reflow process, the photoresist pattern has fluidity and is rounded, and the final shape of the micro lenses 50 is completed. However, as disclosed in FIG. 2C, a gap (G) comes into existence between the micro lenses where the micro lens are formed in the prior art photolithography process of FIGS. 2A-2C.

As disclosed in FIG. 3, when light is emitted from an arbitrary object 70, light incident on the middle micro lens 50 is refracted and accurately focused on the middle photodiode 40, but light incident on the gaps between the middle micro lens 50 and the right and left micro lenses 50 is not accurately focused on the middle photodiode 40. Light incident on the gaps goes straight and thus, is not focused on the middle photodiode 40 because the gaps between the micro lenses 50 are flat. The gaps can thus result in a banding phenomenon in the resulting digital image because light passing through the gaps between the micro lenses 50 goes straight without being focused on the middle photodiode 40. This banding phenomenon results in a deteriorated image quality.

One of the difficulties of forming the prior art micro lenses 50 of FIG. 1 using the prior art photolithography process of FIGS. 2A-2C is the difficulty in uniformly forming the micro lens 50.

For example, the micro lenses 50 formed using the prior art photolithography process of FIGS. 2A-2C have a very low uniformity of Critical Dimension (CD).

It is also difficult to keep the gaps between the micro lenses 50 constant. When the trapezoidal micro lens is melted and controlled in CD during the reflow process discussed above, non-uniform reflow can cause non-uniform gap distances between the micro lenses 50.

In addition, the reflow process discussed above can result in a lens bridges connecting neighbor micro lenses with each other. These lens bridges can result in the banding phenomenon discussed above. An example of this banding phenomenon can be seen in the photograph in FIG. 4.

### SUMMARY OF EXAMPLE EMBODIMENTS

In general, example embodiments of the invention relate to an image sensor having substantially uniform micro lenses and a method of manufacturing the same. The example image sensors disclosed herein generally include micro lenses having a substantially uniform Critical Dimension (CD) resulting in decreased banding phenomenon and improved image quality.

In one example embodiment of the invention, an image sensor includes a semiconductor substrate in which a plurality of photodiodes are formed, an insulating layer formed on the semiconductor substrate, a color filter layer formed on the insulating layer, a planarization layer formed on a whole surface of the resultant comprising the color filter layer and having a plurality of concave parts disposed at regular intervals, and a plurality of micro lenses formed within each of the concave portions of the planarization layer and disposed at regular intervals.

In another example embodiment of the invention, a method for manufacturing an image sensor includes several acts. First, a plurality of photodiodes are formed in a semiconductor substrate. Next, an insulating layer is formed on the semiconductor substrate. Then, a color filter layer is formed on the insulating layer. Next, a planarization layer is formed on a whole surface of the resultant comprising the color filter layer. Then, a photoresist is coated and patterned on a whole surface of the planarization layer resulting in a photoresist pattern. Next, the planarization layer is removed by a predetermined thickness with the photoresist pattern as a mask resulting in a plurality of concave portions disposed at regular intervals. Then, the photoresist pattern is removed. Next, micro lenses are formed within the plurality of concave portions resulting in the micro lenses being disposed at regular intervals.

### BRIEF DESCRIPTION OF THE DRAWINGS

Aspects of example embodiments of the invention will become apparent from the following description of example embodiments given in conjunction with the accompanying drawings, in which:

FIG. 1 is a cross-sectional schematic diagram of a prior art image;

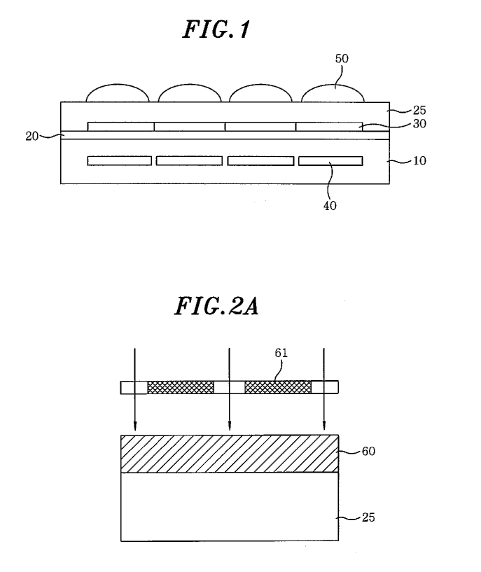

FIGS. 2A-2C are process cross-sectional diagrams of a prior art method for manufacturing the prior art image sensor of FIG. 1;

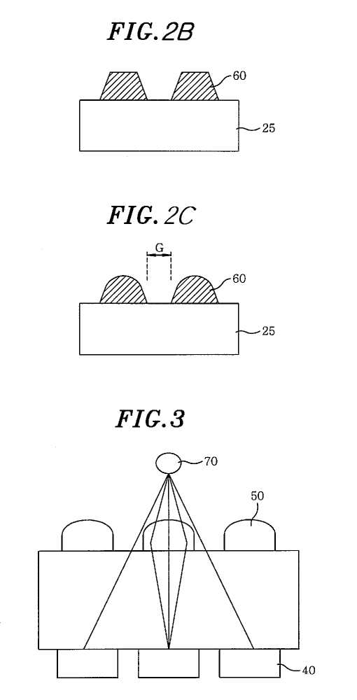

FIG. 3 is a diagram of a path of light passing through a micro lens of the prior art image sensor of FIG. 1;

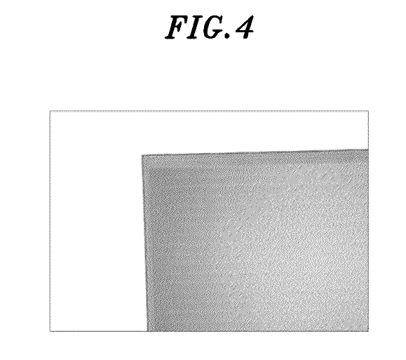

FIG. 4 is a photograph of an image generated using the prior art image sensor of FIG. 1;

FIG. 5 is a cross-sectional schematic diagram of an example image sensor;

FIG. 6 is a photograph of an image generated using the example image sensor of FIG. 5; and

FIGS. 7A-7D are process cross-sectional diagrams of an example method for manufacturing the example image sensor of FIG. 5.

### DETAILED DESCRIPTION OF EXAMPLE EMBODIMENTS

Hereinafter, example embodiments of the invention will be described in detail with reference to the accompanying drawings.

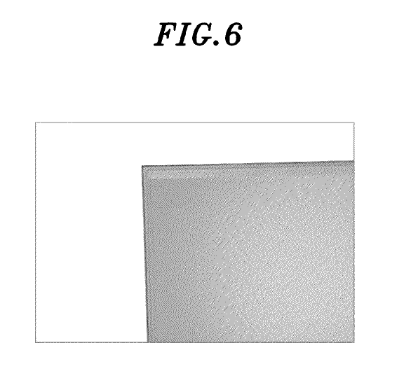

As disclosed in FIG. 5, an example image sensor includes a plurality of photodiodes 400 formed in a semiconductor substrate 100 and an insulating layer 200 formed on the semiconductor substrate 100. A color filter layer 300 is formed on the insulating layer 200 to correspond to the plurality of photodiodes 400. In the color filter layer 300, a red color filter layer 300R or a blue color filter layer 300B is formed to alternate with a green color filter layer 300G in a mosaic format.

A planarization layer 250 is formed to planarize a surface of the color filter layer 300. In one example embodiment, the planarization layer 250 is formed by coating organic material of a photoresist type, or depositing inorganic material such as oxide and nitride, on a surface of the color filter layer 300 and the insulating layer 200.

As disclosed in FIG. 5, a plurality of concave portions are disposed at regular intervals on the planarization layer 250. Example micro lenses 500 are formed in the concave portions and, as a result, the micro lenses 500 have predetermined gaps therebetween. These predetermined gaps prevent any lens bridges being formed between the micro lenses 500 and therefore also prevent the banding phenomenon associated with lens bridges forming between micro lenses.

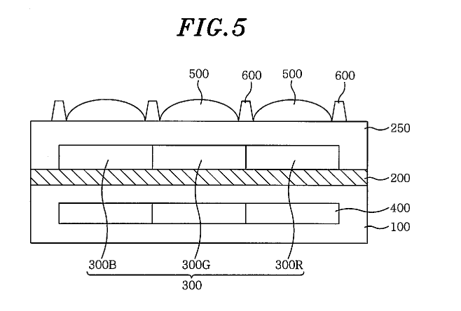

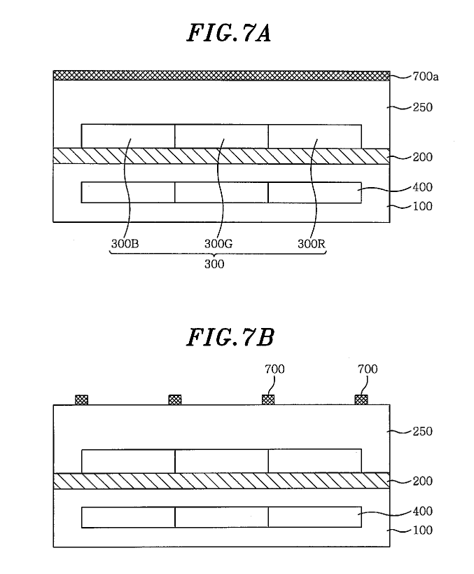

FIG. 6 is a photograph generated using the example image sensor of FIG. 5. As disclosed in FIG. 6, the banding phenomenon of FIG. 4 is not present in the photograph of FIG. 6.

With reference again to FIG. 5, the color filter layer 300 includes a red color filter layer 300R, a green color filter layer 300G, and a blue color filter layer 300B. Each concave portion corresponds to one of the red color filter layer 300R, the green color filter layer 300G, or the blue color filter layer 300B. A plurality of protrusions 600 surrounding the concave portions are formed at boundaries between the red color filter layer 300R, the green color filter layer 300G, and the blue color filter layer 300B. The concave portions are formed to have substantially the same size as each other. The protrusions 600 are formed to have a substantially uniform predetermined width. The width of the protrusions 600 serves as the gap between the micro lenses 500.

As disclosed in FIG. 5, the micro lenses 500 are formed to correspond to the color filter layer 300 and the photodiode 400. Each micro lens 500 focuses light emitted from an object onto the corresponding photodiode 400. In one example embodiment, each micro lens 500 is formed of photoresist or insulating material that has an insulation property and transmits light. The thicknesses of the insulating layer 200 and the planarization layer 250 can be controlled in order to change a focus distance of the micro lenses 500.

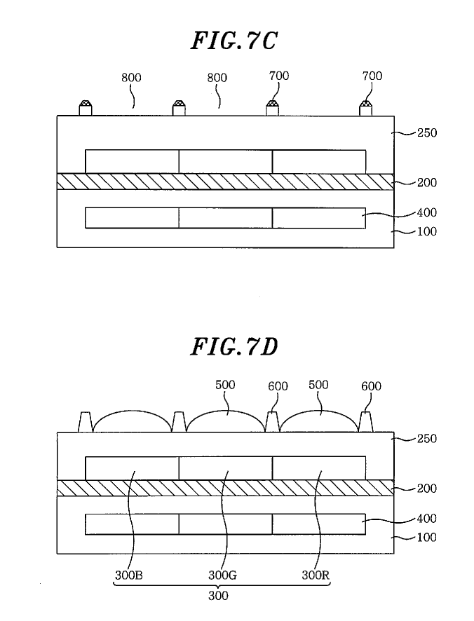

With reference now to FIGS. 7A-7D, an example method for manufacturing the example image sensor of FIG. 5 is disclosed.

As disclosed in FIG. 7A, impurity ions are selectively implanted into a semiconductor substrate 100 and red, green, and blue photodiodes 400 for sensing red, green, and blue signals are formed in a photodiode region of the substrate 100. Next, an insulating layer 200 is formed on the semiconductor substrate 100.

Then, an RGB color filter layer 300 is formed on the insulating layer 200. The RGB color filter layer 300 is formed in a mosaic format. The color filter layer 300 is formed to correspond to the red, green, and blue photodiodes 400. In greater detail, a blue photoresist is coated and is patterned in a photolithography process, thereby forming the blue color filter layer 300B at a position corresponding to the blue photodiode. A red photoresist is coated on a whole surface of the resultant including the blue color filter layer and is patterned in a photolithography process, thereby forming the red color filter layer 300R at a position corresponding to the red photodiode. A green photoresist is coated on a whole surface of the resultant including the red and blue color filter layers 300R and 300B and is patterned in a photolithography process, thereby forming the green color filter layer 300G at a position corresponding to the green photodiode.

Next, a planarization layer 250 is formed to planarize a surface of the resultant by coating organic material of a photoresist type or depositing inorganic material such as oxide and nitride on a whole surface of the resultant including the color filter layer 300. The planarization layer 250 serves as a guide, thereby uniformly forming the micro lenses. A thickness of the micro lenses can be controlled depending on a thickness of the planarization layer 250 and thus, a focus distance can be determined.

Next, a photoresist 700a is coated on the planarization layer 250 and is patterned in a photolithography process. Thus, as disclosed in FIG. 7B, photoresist patterns 700 are formed to have predetermined widths at boundaries between the red, green, and blue color filter layers, 300R, 300G, and 300B, respectively.

As disclosed in FIG. 7C, the planarization layer 250 is ashed by a predetermined thickness with the photoresist pattern 700 as a mask, thereby forming a plurality of concave portions 800. The plurality of concave portions 800 are disposed at regular intervals and have substantially the same size as each other. Each concave portions 800 is formed to correspond to one of the red color filter layer 300R, the green color filter layer 300G, or the B color filter layer 300B.

As disclosed in FIG. 7D, the photoresist pattern 700 remaining on the protrusions 600 is removed. In the removing of the photoresist pattern 700, even the concave portion 800 (see FIG. 7C) of the planarization layer 250 uncovered between the photoresist patterns 700 is identically ashed and thus, the concave portion 800 gets deeper and the protrusion 600 gets thicker. The photoresist pattern can thus be stripped simultaneous to forming the concave portion in the planarization layer.

Next, a plurality of micro lenses 500 are formed by coating a whole surface of the resultant including the concave portion 800 with material having an insulation property and transmitting light and patterning the coated material in a trapezoidal shape in a photolithography process.

The trapezoidal micro lens 500 is heated up to a melting point and reflows. Thus, the trapezoidal micro lens 500 is rounded at its upper corner. Thus, the micro lens 500 having a predetermined pattern is formed and completed in the concave portion 800.

The protrusions 600 surrounding the concave portions 800 are formed at boundaries between the red color filter layer 300R, the green color filter layer 300G, and the blue color filter layer 300B. As disclosed in FIG. 7D, each protrusion 600 is formed to have a predetermined width throughout the image sensor. The width of the protrusions 600 serves as the gap between the micro lenses 500. Thus, the gap between the micro lenses 500 is constantly kept by the predetermined width of the protrusions 600. Despite an excessive reflow of the micro lenses 500, there is no opportunity for the formation of lens bridges between the micro lenses 500 due to the protrusions 600.

The example image sensors and the example methods for manufacturing the same disclosed herein result in gaps between micro lenses that can be uniformly controlled by a predetermined gap of a plurality of protrusions. The uniform micro lenses avoid a deterioration of an image quality due to a banding phenomenon. Further, a photoresist pattern can be removed in an ashing process for forming a concave portion in a planarization layer.

While example embodiments of the invention have been disclosed herein, various changes and modifications may be made without departing from the scope of the invention as defined in the following claims.

What is claimed is:

1. An image sensor comprising:
a semiconductor substrate in which a plurality of photodiodes are formed;
an insulating layer formed on the semiconductor substrate;
a color filter layer formed on the insulating layer;
a planarization layer formed on a whole surface of the resultant comprising the color filter layer and having a plurality of concave parts disposed at regular intervals; and
a plurality of micro lenses formed within each of the concave portions of the planarization layer and disposed at regular intervals.

2. The image sensor of claim 1, wherein the color filter layer is comprised of a red color filter layer, a green color filter layer, and a blue color filter layer.

3. The image sensor of claim 2, wherein the concave portions are formed to correspond to the red color filter layer, the green color filter layer, and the blue color filter layer, respectively.

4. The image sensor of claim 1, wherein the concave portions are formed to have substantially the same size as each other.

5. The image sensor of claim 1, wherein the micro lenses are separated from each other by protrusions of the planarization layer between the concave portions.

6. The image sensor of claim 1, wherein the planarization layer is formed by coating organic material of a photoresist type or depositing inorganic oxide or nitride.

7. A method for manufacturing an image sensor, the method comprising:
forming a plurality of photodiodes in a semiconductor substrate;
forming an insulating layer on the semiconductor substrate;
forming a color filter layer on the insulating layer;
forming a planarization layer on a whole surface of the resultant comprising the color filter layer;
coating and patterning a photoresist on a whole surface of the planarization layer resulting in a photoresist pattern;
removing the planarization layer by a predetermined thickness with the photoresist pattern as a mask resulting in a plurality of concave portions disposed at regular intervals;
removing the photoresist pattern; and
forming micro lenses within the plurality of concave portions resulting in the micro lenses being disposed at regular intervals.

8. The method of claim 7, wherein the planarization layer is formed by coating organic material of a photoresist type or depositing inorganic oxide or nitride.

9. The method of claim 7, wherein an ashing process is performed in the forming of the concave portion in the planarization layer.

10. The method of claim 7, wherein the color filter layer is comprised of a red color filter layer, a green color filter layer, and a blue color filter layer.

11. The method of claim 7, wherein the photoresist pattern is formed to have predetermined widths at boundaries between the red color filter layer, the green color filter layer, and the blue color filter layer.

12. The method of claim 7, wherein the photoresist pattern is removed simultaneous to the forming of the plurality of concave portions.

13. The method of claim 7, wherein the concave portions are formed to correspond to the red color filter layer, the green color filter layer, and the blue color filter layer, respectively.

14. The method of claim 7, wherein the concave portions are formed to have substantially the same size as each other.
